(19) United States
(12) Patent Application Publication
(10) Pub. No.: US 2018/0138074 A1
(43) Pub. Date: May 17, 2018

(54) CARRIER RING AND CHEMICAL VAPOR DEPOSITION APPARATUS INCLUDING THE SAME

(71) Applicant: SAMSUNG ELECTRONICS CO., LTD., SUWON-SI (KR)

(72) Inventors: KYUN-JIN LEE, SUWON-SI (KR); SANG-HOON AHN, GOYANG-SI (KR); MYUNG-JOON PARK, SEOUL (KR); MIN-SAM KIM, HWASEONG-SI (KR); SANG-HOON LEE, SEOUL (KR)

(21) Appl. No.: 15/786,710

(22) Filed: Oct. 18, 2017

Related U.S. Application Data
(60) Provisional application No. 62/420,810, filed on Nov. 11, 2016.

(30) Foreign Application Priority Data
Feb. 16, 2017 (KR) 10-2017-0021025

(51) Int. Cl. H01L 21/687; C23C 16/458

(52) U.S. Cl. CPC H01L 21/68757; C23C 16/4586; C23C 16/4584; H01L 21/68735

(57) ABSTRACT

A pedestal of a CVD apparatus includes a raised central portion, a peripheral portion extending around the central portion, and a carrier ring support disposed along the peripheral portion. A carrier ring of the CVD apparatus includes an annular body disposed over the peripheral portion of the pedestal. The carrier ring is mounted to the pedestal by virtue of the carrier ring support, and in such a way that a lower surface of the annular body is spaced vertically from the peripheral portion of the pedestal and the carrier ring is separable from the pedestal in a vertical direction. A drive mechanism cooperates with carrier ring to lift the carrier ring of the pedestal and mount the carrier ring back onto the pedestal.

### PRIORITY STATEMENT

This application claims the benefit of Korean Patent Application No. 10-2017-0021025, filed on Feb. 16, 2017, in the Korean Intellectual Property Office, the disclosure of which is hereby incorporated by reference in its entirety.

### BACKGROUND

The inventive concept relates to a carrier ring, to a substrate support including the carrier ring and to chemical vapor deposition (CVD) apparatus including the carrier ring.

A CVD apparatus is used to form a thin film on a substrate such as a wafer by facilitating a chemical reaction. More specifically, the CVD apparatus typically injects a reaction gas with a high vapor pressure into a vacuum chamber, containing a substrate, so as to grow a thin film on the substrate via a chemical reaction of the reaction gas.

As the integration degree of semiconductor devices has recently rapidly increased, the need for preventing penetration of foreign substances into a substrate such as a wafer in a manufacturing process of a semiconductor device is increasing. In particular, a thin film may be deposited on an inner wall of a chamber or components in the chamber in a deposition operation. If the thin film is exfoliated from the inner wall and the components of the chamber, the particles of the exfoliated thin film may cause a defect in a semiconductor device. Accordingly, the demand for effectively reducing the amount of particles in chambers of semiconductor device manufacturing apparatus, such as in the chambers of CVD apparatus, has risen.

### SUMMARY

According to an aspect of the inventive concept, there is provided a carrier ring including: a body having an annular shape having a lower surface and an upper surface opposite to the lower surface; a spacer disposed on the lower surface of the body and protruding from the lower surface of the body by a first height; and a protrusion extending downwardly from a lower surface of the spacer.

According to another aspect of the inventive concept, there is provided a substrate support of a chemical vapor deposition (CVD) apparatus, including: a carrier ring having a lower surface and an upper surface opposite to the lower surface; and a pedestal having a carrier ring support for supporting the carrier ring, wherein a wafer is mounted on the pedestal, wherein the carrier ring is configured to be placed on the pedestal such that the lower surface of the carrier ring faces a surface of the pedestal, and wherein the lower surface of the carrier ring includes a first lower surface that contacts the surface of the pedestal when the carrier ring is placed on the pedestal and a second lower surface that is at a different level from the first lower surface and is separated from the surface of the pedestal.

According to another aspect of the inventive concept, there is provided a chemical vapor deposition (CVD) apparatus including: a chamber, a pedestal disposed in the chamber and having a central portion dedicated to support a wafer and a peripheral portion extending around the central portion, an upper surface of the central portion being situated at a level above that of an upper surface of the peripheral portion, a carrier ring disposed on the peripheral portion of the pedestal and mounted to the pedestal in a manner in which the carrier ring is freely separable from the pedestal in a vertical direction, and a transport device including a transport arm configured to engage the carrier ring, and a drive mechanism to which the transport arm is operatively connected so that the transport arm is driven by the drive mechanism. The carrier ring has an upper radially inwardly facing part to surround the wafer supported by the pedestal and an upwardly facing surface extending radially inwardly of the radially inwardly facing part to support an outer peripheral portion of the wafer. Also, the drive mechanism is operable to drive the transport arm vertically between a first position at which the transport arm engages the carrier ring while the carrier ring is mounted to the pedestal and a second position at which the carrier ring is raised off of the pedestal by the transport arm and thereby separated from the pedestal.

According to still another aspect of the inventive concept, there is provided a chemical vapor deposition (CVD) apparatus including: a chamber, a pedestal disposed in the chamber and including a central portion having an upper surface, a peripheral portion extending around the central portion and having an upper surface disposed at a level beneath that of the upper surface of the central portion, and carrier ring supports disposed along an outer circumference of the peripheral portion, and a carrier ring mounted to the pedestal via the carrier ring supports. The carrier ring comprises an annular body having an upper surface disposed radially outwardly of the central portion of the pedestal, and a lower surface disposed radially inwardly of the carrier ring supports. Also, the lower surface of the annular body extends over and is vertically spaced from the upper surface of the peripheral portion of the pedestal.

According to still another aspect of the inventive concept, there is provided a chemical vapor deposition (CVD) apparatus including: a chamber, a pedestal disposed in the chamber and having a central portion having an upper surface, a peripheral portion extending around the central portion and having an upper surface disposed at a level beneath that of the upper surface of the central portion, and carrier ring supports disposed along the peripheral portion of the pedestal, a carrier ring mounted to the pedestal at the carrier ring supports, the carrier ring having an upper surface disposed radially outwardly of the central portion of the pedestal and a lower surface facing the upper surface of the peripheral portion of the pedestal, and a transport device including a transport arm configured to engage the carrier ring, and a drive mechanism to which the transport arm is operatively connected. The carrier ring and carrier ring supports have complementary portions fitted to one another, and the complementary portions configured such that the carrier ring is freely separable from the pedestal in a vertically upward direction. The drive mechanism is operable to drive the transport arm vertically between a first position at which the transport arm engages the carrier ring while the carrier ring is mounted to the pedestal and a second position at which the carrier ring is raised off of the pedestal by the transport arm and thereby separated from the pedestal.

### BRIEF DESCRIPTION OF THE DRAWINGS

The inventive concept will be more clearly understood from the following detailed description of examples thereof taken in conjunction with the accompanying drawings in which:

FIG. 1 is a partial cross-sectional view of an example of a pedestal and carrier ring of a chemical vapor deposition (CVD) apparatus according to the inventive concept, in a state in which the pedestal and carrier ring contact each other;

FIG. 2 is a perspective view of the pedestal illustrated in FIG. 1;

FIG. 3 is an enlarged view of region III of FIG. 1;

FIG. 4 is a graph showing a growth rate of material deposited on a carrier ring according to temperature of the carrier ring;

FIG. 5A is a diagram illustrating a temperature distribution of a conventional carrier ring;

FIG. 5B is a graph showing a temperature of the carrier ring of FIG. 5A near an inner edge and a temperature of the carrier ring of FIG. 5A near an outer edge over time;

FIG. 6A is a diagram illustrating a temperature distribution of an example of a carrier ring according to the inventive concept;

FIG. 6B is a graph showing a temperature of the carrier ring of FIG. 6A near an inner edge and a temperature of the carrier ring of FIG. 6A near an outer edge over time;

FIG. 7A is a diagram illustrating a temperature distribution of an example of a carrier ring according to the inventive concept;

FIG. 7B is a graph showing a temperature of the carrier ring of FIG. 7A near an inner edge and a temperature of the carrier ring of FIG. 7A near an outer edge over time;

FIGS. 8 and 9 are bottom views of examples of a carrier ring according to the inventive concept;

FIG. 10 is a partial cross-sectional view of a peripheral region of an example of a pedestal and carrier ring according to the inventive concept, corresponding to that illustrated in FIG. 3;

FIG. 11 is a partial cross-sectional view of a peripheral region of another example of a pedestal and carrier ring according to the inventive concept, corresponding to that illustrated in FIG. 3;

FIG. 12 is a partial cross-sectional view of a peripheral region of still another example of a pedestal and carrier ring according to the inventive concept, corresponding to that illustrated in FIG. 3;

FIG. 13 is a schematic cross-sectional view of a CVD apparatus according to the inventive concept;

FIG. 14 is a plan view of a lower chamber in the CVD apparatus of FIG. 13;

FIG. 15 is a detailed view of a transport arm illustrated in FIG. 14;

FIG. 16 is a flowchart of an example of a manufacturing process of a semiconductor device, according to the inventive concept;

FIG. 17 is a table of states of a wafer, carrier ring and pedestal in conditioning operations and a deposition operation in the manufacturing process illustrated in FIG. 16; and

FIG. 18 is a cross-sectional view of a carrier ring and a pedestal in a state in which the carrier ring and pedestal are not in contact with each other.

### DETAILED DESCRIPTION

The inventive concept will now be described more fully with reference to the accompanying drawings, in which examples of the inventive concept are shown.

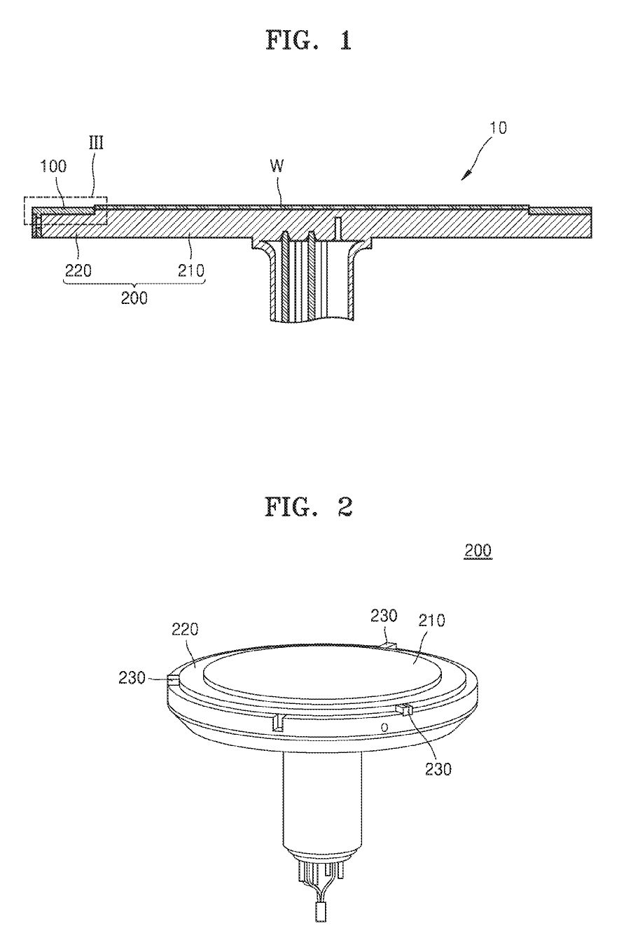

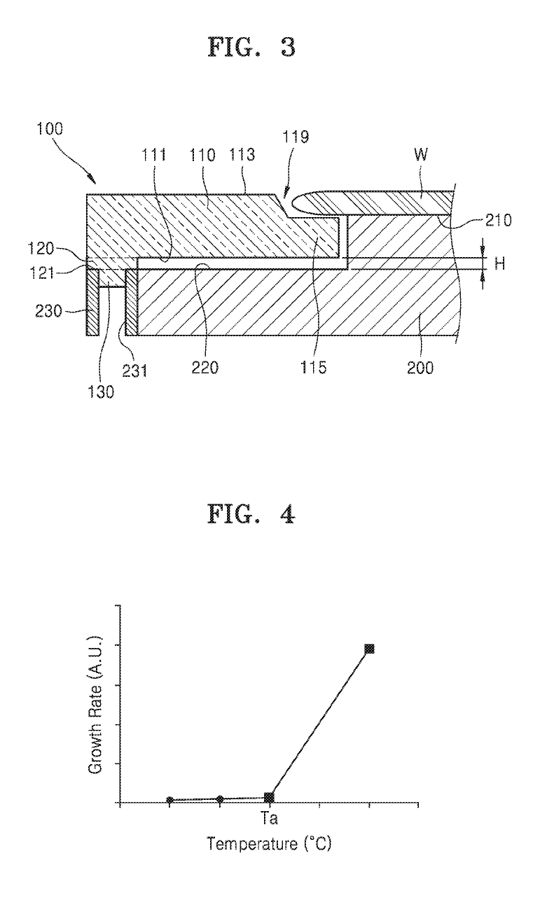

FIG. 1 is a partial cross-sectional view of a substrate support 10 of a chemical vapor deposition (CVD) apparatus according to the inventive concept. FIG. 2 is a perspective view of a pedestal 200 of the substrate support 10 illustrated in FIG. 1. FIG. 3 is an enlarged view of region III of FIG. 1.

Referring to FIGS. 1 through 3, the substrate support 10 may include the pedestal 200 and a carrier ring 100.

The pedestal 200 may support a wafer W during a deposition operation. The pedestal 200 may include a central portion 210 where the wafer W is disposed and a peripheral portion 220 where the carrier ring 100 is disposed. The central portion 210 may provide a flat surface on which the wafer W may rest, and the peripheral portion 220 may provide a flat surface on which the carrier ring 100 is to rest. The surface provided by the central portion 210 may be at a higher level than the surface provided by the peripheral portion 220.

Although not illustrated in the drawings, lift pins may be disposed within the central portion 210 of the pedestal 200. The lift pins may be connected to a lift mechanism within a chamber 301 (see FIG. 13) in which a deposition operation on the wafer W is performed. The lift pins may be brought by the lift mechanism to a pin-up state, in which the lift pins project upwardly from the central portion 210 of the pedestal 200 to receive a wafer W loaded into the chamber 301 or to support the wafer W while the wafer W is being unloaded from the chamber 301. In addition, the lift pins may be brought from the pin-up state to a pin-down state, in which the lift pins are disposed within the pedestal 200 to set the wafer W on the pedestal 200. The lift pins may remain retracted within the pedestal 200 during a deposition operation in which the wafer W is disposed on the pedestal 200.

The pedestal 200 may include carrier ring supports 230 to contact and support the carrier ring 100. The carrier ring supports 230 may be mounted near the peripheral portion 220 of the pedestal 200. The carrier ring supports 230 may be radially spaced apart from one another along an outer circumference of the peripheral portion 220 of the pedestal 200. The carrier ring supports 230 may each include a hole 231 to accommodate a protrusion 130 of the carrier ring 100.

Although not illustrated in the drawings, a heating member to heat the wafer W may be integrated with the pedestal 200. During a deposition operation, the heating member may heat the wafer W to a predetermined temperature in a process of forming a thin film on the wafer W.

The carrier ring 100 may be used to transport the wafer W in a chamber in which a deposition operation is performed. While the wafer W is being transported, the carrier ring 100 may support a lower portion of an edge area of the wafer W, i.e., may support the wafer by its bottom at an outer peripheral portion of the wafer W.

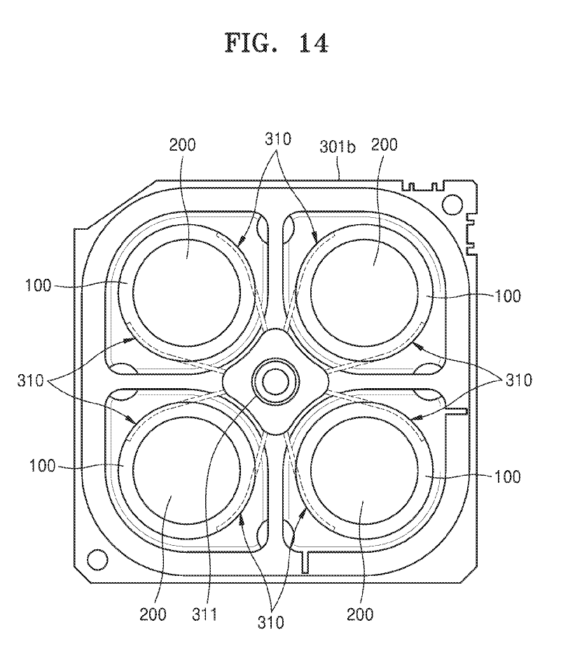

More specifically, when the wafer W is transported between multiple stations in a chamber, a transport arm 310 (see FIG. 14) may transport the carrier ring 100 and the wafer W together. The transport arm 310 may lift, horizontally move and/or lower the carrier ring 100 so as to transport the carrier ring 100 and the wafer W supported by the carrier ring 100 between the multiple stations. Moving the carrier ring 100 horizontally is necessary to move the carrier ring 100 from an upper portion of one station to an upper portion of another station.

According to the present example, the carrier ring 100 has an annular planar structure, and may include a body 110, a spacer 120, and a protrusion 130. However, a carrier ring according to the inventive concept is not limited to having such an annular planar structure. In this regard, the structure of the carrier ring simply may depend on the structure of the pedestal 200 on which the carrier ring 100 is disposed.

When the carrier ring 100 is disposed on the pedestal 200, as illustrated in FIG. 1, the carrier ring 100 may be disposed on the pedestal 200 with a radially inwardly facing part thereof surrounding the wafer W resting on and supported by the central portion 210 of the pedestal 200. That part may define an upper radially inwardly facing side surface in the form of an inverted frustum. For example, as shown in FIG. 3, the carrier ring 100 has the upper radially inwardly facing side surface to surround the wafer W supported by the pedestal 200 and an upper or upwardly facing surface (of inner peripheral portion 115) extending radially inwardly from the bottom of the radially inwardly facing side surface to support an outer peripheral portion of the wafer. The upper radially inwardly facing side surface and the upper surface of the carrier ring 100 together have the form of a nest. The wafer W is thus prevented from moving laterally relative to the carrier ring 100 especially when being transported as supported by the carrier ring 100.

The body 110 constitutes the bulk of the carrier ring 100, and thus, may have an annular and planar structure. The body 110 may have a lower surface 111 and an upper surface 113 that face in opposite directions. When the carrier ring 100 is disposed on the pedestal 200, the lower surface 111 of the body 110 may face a surface of the pedestal 200. The carrier ring 100 described here is understood as including the body 110, the spacer 120, and the protrusion 130, and the body 110 may refer to a portion of the carrier ring 100 minus the spacer 120 and the protrusion 130. In addition, the bottom surface of the carrier ring 100 may include the lower surface 111 of the body 110 and a lower surface 121 of the spacer 120.

The inner peripheral portion 115 of the body 110 may extend below an edge area of the wafer W. That is, when the carrier ring 100 is disposed on the pedestal 200, the inner peripheral portion 115 of the carrier ring 100 may be vertically juxtaposed with and may overlap the edge area of the wafer W. The inner peripheral portion 115 of the body 110 may contact and support a lower portion of the edge area of the wafer W while the wafer W is being transported.

The spacer 120 may space the lower surface 111 of the body 110 from the pedestal 200 when the carrier ring 100 is disposed on the pedestal 200. The spacer 120 protrudes from the lower surface 111 of the body 110 by a predetermined amount corresponding to the height or thickness of the spacer 120. For example, when the carrier ring 100 is disposed on the pedestal 200, the lower surface 121 of the spacer 120 may contact an upper surface of the carrier ring support 230. As the spacer 120 directly contacts the pedestal 200, the lower surface 111 of the body 110 may be separated from the pedestal 200.

Accordingly, when the wafer W and the carrier ring 100 are heated using the pedestal 200, heat transfer between the carrier ring 100 and the pedestal 200 may be conducted predominately via the spacer 120.

The spacer 120 may be disposed near an outer edge of the carrier ring 100. Consequently, a local temperature of the carrier ring 100 near the outer edge of the carrier ring 100 may rapidly increase compared to that of a portion of the carrier ring 100 near the inner edge of the carrier ring 100. Accordingly, until the overall temperature of the carrier ring 100 becomes almost uniform, a local temperature of the carrier ring 100 near the outer edge of the carrier ring 100 may be higher than that of the portion of the carrier ring 100 near the inner edge of the carrier ring 100.

When the carrier ring 100 is disposed on the pedestal 200, a vertical distance H between the lower surface 111 of the body 110 and the pedestal 200 may be approximately equal to a height of the spacer 120. The lower surface 111 of the body 110 and a surface of the pedestal 200 facing the lower surface 111 of the body 110 may be flat surfaces. In addition, the lower surface 111 of the body 110 may be substantially parallel to the surface of the pedestal 200 facing the lower surface 111 of the body 110.

In some examples, the lower surface 121 of the spacer 120 may be substantially parallel to the lower surface 111 of the body 110.

The vertical distance H between the lower surface 111 of the body 110 and the pedestal 200 may be greater than 0.15 mm. In some examples, the vertical distance H between the lower surface 111 of the body 110 and the pedestal 200 may be in a range of from about 0.5 mm to about 2.0 mm More preferably, the vertical distance H between the lower surface 111 of the body 110 and the pedestal 200 is in a range of from about 1.0 mm to about 2.0 mm.

The protrusion 130 may have a structure extending downwardly from a lower surface of the carrier ring 100. More specifically, the protrusion 130 may be disposed on the lower surface 121 of the spacer 120. When the carrier ring 100 is disposed on the pedestal 200, the protrusion 130 may be accommodated in the hole 231 in the carrier ring support 230. In this way, i.e., because the shapes of the protrusion 130 and the hole 231 are complementary whereby a precise fit is provided between the protrusion 130 and carrier ring support 230, the carrier ring 100 may be aligned with the pedestal 200.

When the protrusion 130 is accommodated in the hole 231 of the carrier ring support 230, at least a portion of a surface of the protrusion 130 may contact the carrier ring support 230. As the protrusion 130 contacts the carrier ring support 230, heat of the pedestal 200 at a high temperature may be conducted to the protrusion 130 as well as to the spacer 120.

A vertical cross section of the protrusion 130 may be rectangular as illustrated in FIG. 3. However, the vertical cross section of the protrusion 130 is not limited to being rectangular and may instead, for example, have a downward-tapering shape, i.e., the shape of an inverted frustum.

The protrusion 130 may be formed at locations corresponding to the carrier ring supports 230. For example, as illustrated in FIG. 2, when three carrier ring supports 230 are radially spaced apart from one another, the protrusion 130 may include three portions that are radially spaced from one another at intervals equal to those at which the carrier ring supports 230 are radially spaced from each other.

The carrier ring 100 may be formed of alumina (Al₂O₃), quartz, yttrium oxide (Y₂O₃), silicon carbide (SiC), silicon oxide (SiO₂), TEFLON, or a combination of two or more of these materials.

In some examples, the carrier ring 100 may be formed of a material having relatively low heat conductivity. For example, the carrier ring 100 may be formed of a material having a thermal conductivity of less than 29 W/m·K.

In some examples, the carrier ring 100 is formed of quartz or Y₂O₃. When the carrier ring 100 is formed of quartz or Y₂O₃ having relatively low heat conductivity, a rapid increase in a temperature of the carrier ring 100 due to the pedestal 200, which is at a high temperature, may be prevented.

In examples of the inventive concept, the carrier ring 100 does not directly contact the pedestal 200 except for the spacer 120 and the protrusion 130, and thus, an amount of heat transfer between the carrier ring 100 and the pedestal 200 may be kept to a minimum. Accordingly, while a deposition operation is performed, a temperature increase of the carrier ring 100 may be gradual.

More specifically, while the pedestal 200 heats the wafer W at a deposition process temperature for forming a thin film on the wafer W, the carrier ring 100 may be heated by the pedestal 200 to a temperature lower than the process temperature. As a result, a thickness of a thin film deposited on the carrier ring 100 may be significantly less than a thickness of a thin film formed on the wafer W.

Meanwhile, for example, if a thin film deposited on the carrier ring 100 were exfoliated from the carrier ring 100 due to oscillation generated during a transport operation of the wafer W, the transferred thin film could cause a defect in a device. In particular, a thin film if exfoliated near an inner edge of the carrier ring 100 would likely be transferred to the edge area of the wafer W, and this may decrease a yield of products formed from the wafer W. However, according to the inventive concept, the carrier ring 100 is configured to keep its temperature to a minimum so that deposition of a thin film-forming material on the carrier ring 100, which may be a cause of defects in the device, may be minimized.

FIG. 4 is a graph showing a growth rate of material deposited on a carrier ring according to temperature of the carrier ring.

As illustrated in FIG. 4, the growth rate of a thin film formed on a carrier ring gradually increases for temperature increases of the carrier ring below an inflection temperature Ta. However, the growth rate of the thin film abruptly increases for temperature increases beyond the inflection temperature Ta. The growth rate of the thin film may represent a thickness of the thin film formed on the carrier ring per each cycle.

The inflection temperature Ta may be lower than the process temperature for depositing the thin film-forming material on a wafer, that is, the temperature of a heated pedestal.

The inflection temperature Ta depends on the type of a thin film being formed, a process condition of the deposition operation, or the like. For example, in an operation for depositing an AlN layer, when a temperature of a pedestal is about 350° C., the inflection temperature Ta may be about 250° C. By performing the deposition operation while controlling a temperature of the carrier ring to be about 250° C. or lower, hardly any AlN may be deposited on the carrier ring while a substantial AlN layer is formed on a wafer that is heated to a temperature of almost 350° C. by the pedestal.

Accordingly, by maintaining the temperature of the carrier ring at the inflection temperature Ta or lower, deposition on the carrier ring may be minimized That is, when the temperature of the carrier ring is the inflection temperature Ta or lower, the thin film may be grown on a surface of the carrier ring in a self-limiting manner.

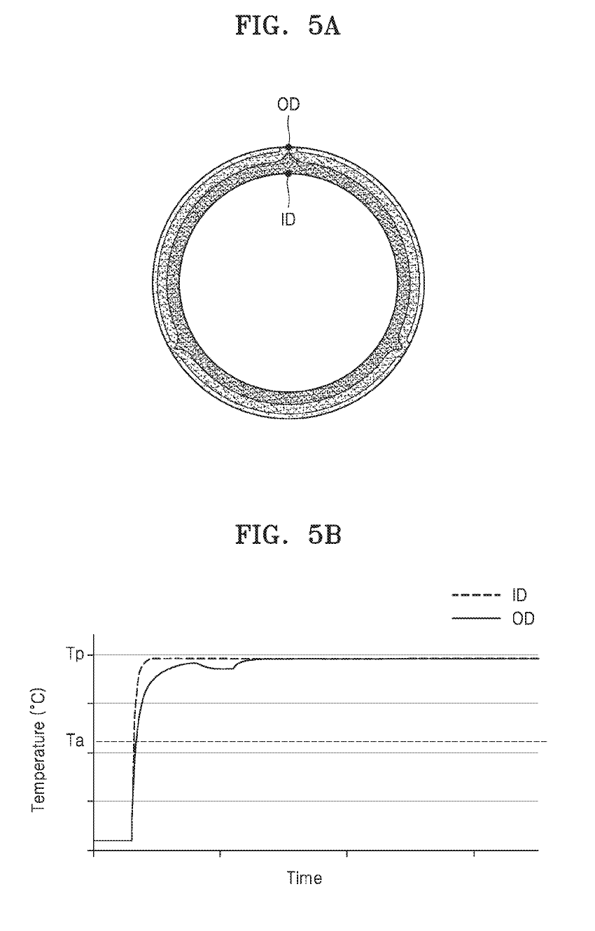

FIG. 5A illustrates a temperature distribution of a conventional carrier ring. FIG. 5B is a graph showing a temperature of a portion of the carrier ring near an inner edge ID in FIG. 5A and a temperature of a portion of the carrier ring near an outer edge OD in FIG. 5A over time.

Referring to FIGS. 5A and 5B, unlike the examples of the inventive concept, a conventional carrier ring having a structure in which most portions of a lower surface of the carrier ring contact a pedestal is illustrated. FIG. 5A shows a temperature distribution of the carrier ring before a temperature of the carrier ring near the inner edge ID equals a temperature of the carrier ring near the outer edge OD. In FIG. 5B, a dashed line denotes a temperature of the carrier ring near the inner edge ID, and a solid line denotes a temperature of the carrier ring near the outer edge OD.

As illustrated in FIG. 5A, the temperature of the carrier ring near the inner edge ID is higher than the temperature of the carrier ring near the outer edge OD. That is, a portion of the carrier ring near the inner edge ID may be heated faster than a portion of the carrier ring near the outer edge OD.

Meanwhile, as illustrated in FIG. 5B, both portions of the carrier ring near the outer edge OD and the inner edge ID are heated up to approximately the temperature of the pedestal within a relatively short time period.

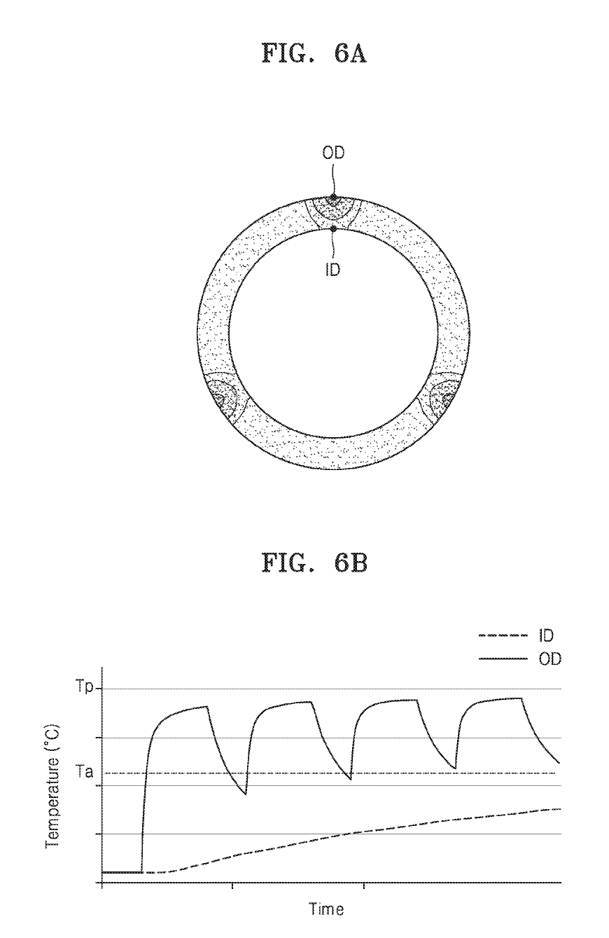

FIG. 6A illustrates a temperature distribution of a carrier ring according to some examples of the inventive concept. FIG. 6B is a graph showing a temperature of the carrier ring of FIG. 6A near an inner edge ID and a temperature of the carrier ring of FIG. 6A near an outer edge OD over time. Referring to FIGS. 6A and 6B, a temperature distribution of the carrier ring 100 and a change in a temperature of the carrier ring 100 over time will be described with reference to the carrier ring 100 illustrated in FIG. 3.

Referring to FIGS. 6A and 3 together, a temperature of the carrier ring 100 is relatively high near the spacer 120 which is in contact with the pedestal 200, and decreases away from the spacer 120. That is, most heat transfer between the pedestal 200 and the carrier ring 100 is conducted via the spacer 120 that is in contact with the pedestal 200, and accordingly, a temperature near the spacer 120 may increase relatively fast compared to other portions of the carrier ring 100 and may be relatively high compared to the other portion of the carrier ring 100 until the overall temperature of the carrier ring 100 becomes uniform. On the other hand, portions away from the spacer 120, for example, a portion near the inner edge ID of the carrier ring 100 is heated relatively slow, and thus, a temperature of the carrier ring 100 near the inner edge ID may be relatively low.

As illustrated in FIG. 6B, a portion of the carrier ring 100 near the inner edge ID may gradually increase compared to a portion of the carrier ring 100 near the outer edge OD. In addition, while a temperature of the carrier ring 100 near the outer edge OD exceeds the inflection temperature Ta, a temperature of the carrier ring 100 near the inner edge ID may be lower than the inflection temperature Ta.

More specifically, a temperature of the carrier ring 100 near the outer edge OD may increase relatively fast to reach a temperature close to a process temperature Tp and then decrease. A decrease in the temperature of the carrier ring 100 near the outer edge OD occurs because the carrier ring 100 is separated from the pedestal 200, which is a heat source, while the wafer W is transported between stations. While the wafer W is transported between the stations, heat of the carrier ring 100 near the outer edge OD, which is at a relatively high temperature, is transferred to the portion of the carrier ring 100 near the inner edge ID, which is at a relatively low temperature. Accordingly, the temperature of the carrier ring 100 near the outer edge OD may decrease, and the temperature of the carrier ring 100 near the inner edge ID may increase.

As a cycle progresses, the temperature of the carrier ring 100 near the outer edge OS repeatedly increases and decreases, and the temperature of the carrier ring 100 near the inner edge ID may gradually increase. As time passes, the temperature of the carrier ring 100 near the inner edge ID may become almost equal to the temperature of the carrier ring 100 near the outer edge OD.

Compared to the conventional carrier ring whose characteristics are depicted in FIGS. 5A and 5B, a portion of the carrier ring 100 according to the inventive concept, corresponding to the inner edge ID, has a temperature equal to or less than the inflection temperature Ta for a considerably longer amount of time. Thus, deposition of a thin film-forming material on a portion of the carrier ring 100 near the inner edge ID may be minimized.

In addition, according to an aspect of the inventive concept, while a plurality of cycles are conducted, the carrier ring 100 is gradually heated to a temperature approaching that of the pedestal 200, which is at a high temperature. However, by delaying a point when the temperature of the carrier ring 100 near the inner edge ID reaches the inflection point Ta, the lifespan of the carrier ring 100 may be extended.

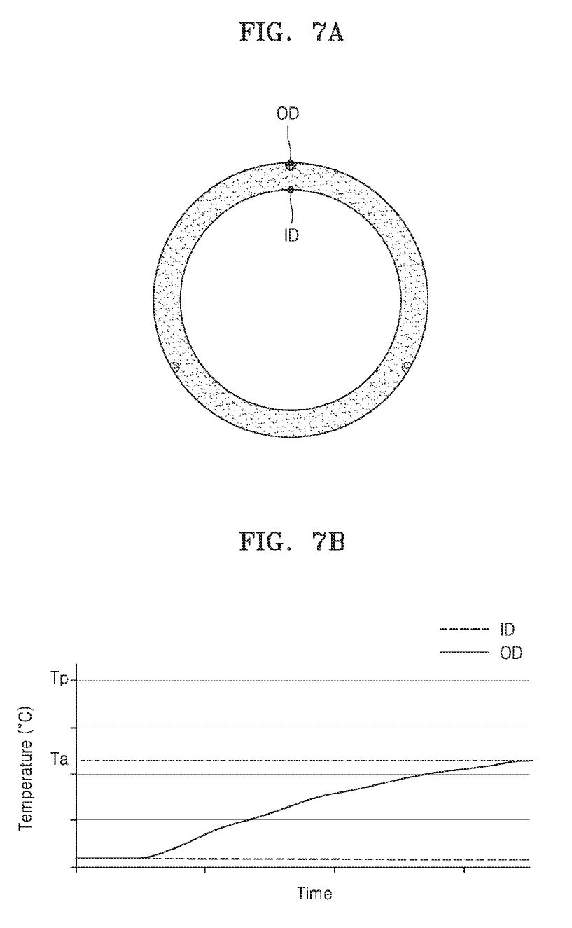

FIG. 7A illustrates a temperature distribution of a carrier ring according to some examples of the inventive concept. FIG. 7B is a graph showing a temperature of the carrier ring of FIG. 7A near an inner edge and a temperature of the carrier ring of FIG. 7A near an outer edge over time. As with respect to FIGS. 6A and 6B, for the description of FIGS. 7A and 7B, a temperature distribution of the carrier ring 100 and a change in a temperature of the carrier ring 100 over time will be described with reference to the carrier ring 100 illustrated in FIG. 3.

However, in FIGS. 7A and 7B, the temperature distribution is one for the carrier ring 100 when formed of a material having lower thermal conductivity than that of the carrier ring 100 whose characteristics are shown in FIGS. 6A and 6B, such as quartz or Y₂O₃, and a change in the temperature of the carrier ring 100 formed of the above material over time are illustrated.

Referring to FIGS. 7A and 3, as in the example illustrated by FIG. 6A, a temperature of the carrier ring 100 is relatively high in a portion near the spacer 120 that is in contact with the pedestal 200. However, because the carrier ring 100 has a lower thermal conductivity than the carrier ring 100 whose temperature distribution is shown in FIG. 6A, a temperature of a portion of the carrier ring 100 near the spacer 120 that is in contact with the pedestal 200 may be lower.

As illustrated in FIG. 7B, a portion of the carrier ring 100 near the inner edge ID may gradually increase compared to a portion of the carrier ring 100 near the outer edge OD. Compared to the example characterized by FIG. 6B, the carrier ring 100 has a lower thermal conductivity, and accordingly, a temperature of the carrier ring 100 near the inner edge ID may increase more slowly. Thus, a time when the temperature of the carrier ring 100 near the inner edge ID reaches the inflection temperature Ta may be delayed to a greater degree.

In addition, compared to the example characterized by FIG. 6B, because the carrier ring 100 has a lower thermal conductivity, temperatures of the carrier ring 100 both near the inner edge ID and the outer edge OD may increase even more slowly. Furthermore, compared to the example characterized by FIG. 6B, a temperature difference between the portion of the carrier ring 100 near the inner edge ID and the portion of the carrier ring 100 near the outer edge OD may be reduced, and a thermal conductivity of the carrier ring 100 is lower, and thus, a section where the temperature of the carrier ring 100 near the outer edge OD decreases may not be generated even during transportation of the wafer W between stations.

According to some examples of the inventive concept, not only is a contact area between the carrier ring 100 and the pedestal 200 minimized but the carrier ring 100 is formed of material having a relatively low thermal conductivity. Accordingly, deposition of a thin film-forming material on the carrier ring 100 may be minimized. In addition, defects caused by exfoliation of the thin film from the carrier ring 100 may be prevented.

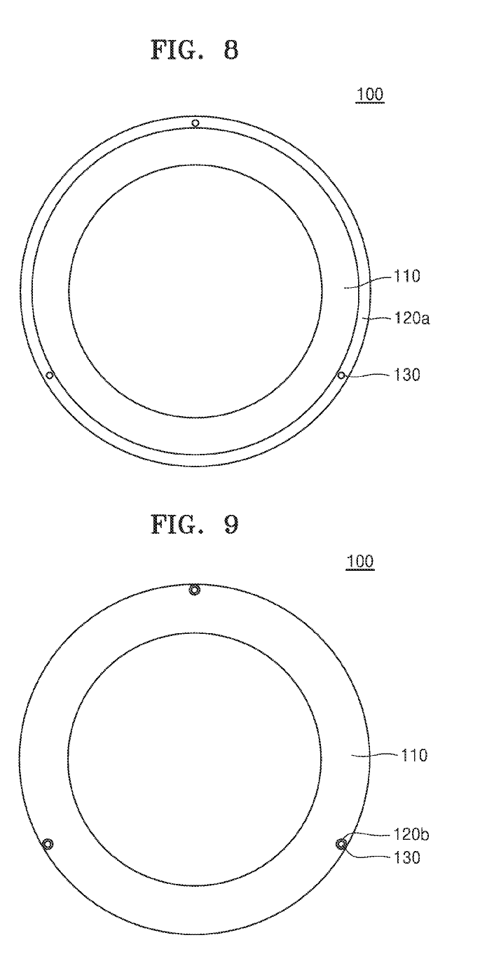

FIGS. 8 and 9 are bottom views of the carrier ring 100 for nest showing examples of the spacer. Descriptions already given above with reference to FIGS. 1 through 3 are omitted or briefly provided.

Referring to FIG. 8, the spacer 120a may have a structure extending along an outer edge of the carrier ring 100. For example, the spacer 120a may continuously extend along the outer edge of the carrier ring 100, and may have a ring shape. The spacer 120a may have an annular lower surface.

However, according to another example, the spacer may also extend discontinuously along the outer edge of the carrier ring 100. That is, the spacer may extend over the entire outer edge of the carrier ring 100 but there may be gaps between (arcuate) sections of the spacer.

Referring to FIG. 9 along with FIG. 3, a spacer 120b may include a plurality of portions disposed near the outer edge of the carrier ring 100. For example, the spacer 120b may include three portions that are radially spaced apart from each other to respectively correspond to the three carrier ring supports 230. A lower surface of the spacer 120b may contact an upper surface of the carrier ring supports 230 so as to provide a sufficient area to stably support the carrier ring 100.

However, according to another embodiment, a spacer may include more portions than the number of carrier ring supports 230. For example, besides the three portions that are radially spaced apart from one another to respectively correspond to the three carrier ring supports 230, the spacer may further include three more portions that are each disposed between adjacent carrier ring supports 230. In this case, the three portions disposed between the adjacent carrier ring supports 230 may be configured to contact the pedestal 200 so that the carrier ring 100 is supported by the pedestal 200 even more stably.

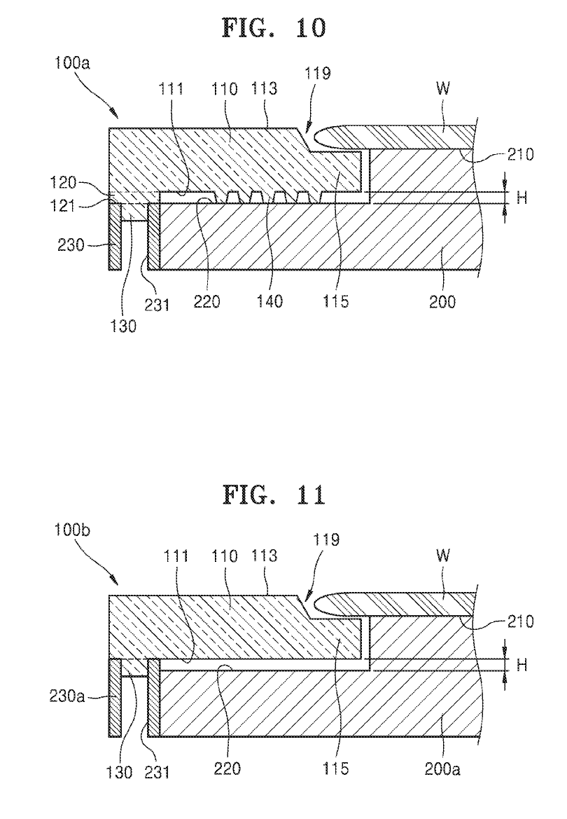

FIG. 10 is a partial cross-sectional view of another example of a substrate support of the inventive concept, which corresponds to FIG. 3. A carrier ring 100a illustrated in FIG. 10 may have a similar structure as the carrier ring 100 illustrated in FIG. 3 except that the carrier ring 100a further includes a concave-convex (i.e., undulating) section 140. In FIG. 10, like reference numerals as those in FIG. 3 denote like elements, and descriptions of the elements are omitted or briefly provided.

Referring to FIG. 10, the carrier ring 100a may include the concave-convex section 140 in addition to the body 110, the spacer 120, and the protrusion 130. The concave-convex section 140 may be disposed radially inwardly of and be contiguous with the lower surface 111 of the body 110. The concave-convex section 140 may have an approximately identical height to a height of the spacer 120, e.g., the distance H by which the spacer 120 vertically extends from the lower surface 111 of the body 110. When the carrier ring 100a is placed on the pedestal 200, the concave-convex section 140 may contact the pedestal 200.

Because of the provision of the concave-convex section 140, the carrier ring 100a may be stably supported by the pedestal 200. That is, when the carrier ring 100a is placed on the pedestal 200, a portion of the carrier ring 100a besides the portion thereof near the outer edge may also be supported by the pedestal 200 via the concave-convex section 140, and thus, tilting of the carrier ring 100a to one side may be prevented.

The concave-convex section 140 may be formed by removing part of a lower portion of the carrier ring. As a result, compared to a carrier ring in which the entire such lower portion of the carrier ring is in contact with the pedestal 200, less contact area exists between the carrier ring 100a and the pedestal 200. Accordingly, an abrupt increase in a temperature of the carrier ring 100a due to the pedestal 200 may be prevented.

The convexities of the concave-convex section 140 may have a downward-tapering structure. For example, a vertical cross section of each convexity of the concave-convex section 140 may have the shape of a trapezoid as illustrated in FIG. 10. However, the concave-convex section 140 is not limited thereto. For example, each convexity of the concave-convex section 140 may have a triangular or conical cross section so that the concave-convex section 140 and the upper surface of the peripheral portion 220 of the pedestal 200 are in point or line contact.

The concave-convex section 140 may be disposed between the spacer 120 and a radially inner peripheral edge of the carrier ring 100. The radially inner peripheral edge may be the inner edge of the body 110 adjacent to a radially outer peripheral surface of the central portion 210 of the pedestal 200. (In FIG. 10, the inner edge is that from which the upper line illustrating the dimension H extends.) The concave-convex section 140 is illustrated here as being disposed in some sections between the spacer 120 and the inner edge of the body 110, but is not limited thereto. For example, the concave-convex section 140 may be continuously disposed between the spacer 120 and the inner edge of the body 110.

In addition, the concave-convex section 140 may be formed over the entire lower portion of the body 110. Alternatively, the concave-convex section 140 may be disposed in between respective sections of the lower surface 111 of the body 110, and in this case, the lower surface 111 of the body 110 may have several discrete sections separated from each other by the concave-convex section.

In these cases, the lower surface 111 (or section thereof) may be distinguished from the concave-convex section 140 in that the lower surface 111 (or section thereof) extends radially over a greater distance than the bottoms of the concavities between adjacent ones of the convexities. On the other hand, the lower portion of the body 110 may more simply be considered as having the lower surface 111 and a convexity or a series of such convexities as arrayed in the radial direction of the carrier ring 100a protruding downwardly from the lower surface 111.

FIG. 11 is a partial cross-sectional view of another example of a substrate support of the inventive concept, which corresponds to FIG. 3. The carrier ring 100b illustrated in FIG. 11 may have a similar structure as the carrier ring 100 illustrated in FIG. 3 except that the carrier ring 100b does not include the spacer 120 (see FIG. 3). In addition, a carrier ring support 230a of the pedestal 200 illustrated in FIG. 11 may have a similar structure as the carrier ring supports 230 illustrated in FIG. 3 except that the carrier ring support 230a protrudes upwardly from the peripheral portion 220 of the pedestal 200. In FIG. 11, like reference numerals as those in FIG. 3 denote like elements, and descriptions of the elements are omitted or briefly provided. Thus, it may be considered that the carrier ring 100b has a first section that contacts the carrier ring support 230a and a protrusion 130 that extends downwardly from the first section and is received in the hole 231 in the carrier ring support 230a.

More specifically and still referring to FIG. 11, the carrier ring support 230a protrudes from the peripheral portion 220 of the pedestal 200 by a predetermined height, and may directly support the lower surface 111 of the body 110. When the carrier ring 100b is placed on the pedestal 200, the carrier ring support 230a may support the carrier ring 100b such that the lower surface 111 of the body 110 is separated from the pedestal 200. In this case, a vertical distance H over which the lower surface 111 of the body 110 is separated from the surface of the pedestal 200 may be approximately the same as the distance over which the carrier ring support 230a protrudes from the peripheral portion 220 of the pedestal 200.

The carrier ring 100b does not include the spacer 120, and thus, the almost the entire bottom of carrier ring 100b may be planar. Because the carrier ring support 230a has a protruding structure from the peripheral portion 220 of the pedestal 200, and the carrier ring 100b has a planar lower surface except for a portion corresponding to the protrusion 130, a large lower surface 111 of the body 110 may be separated from the pedestal 200.

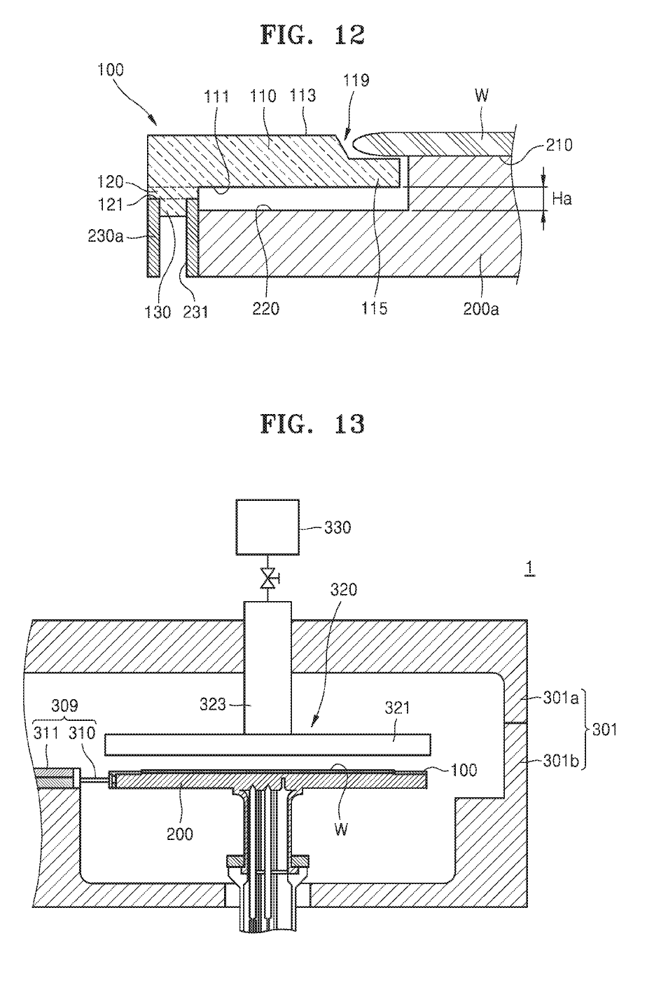

FIG. 12 is a partial cross-sectional view of still another example of a substrate support of the inventive concept, which corresponds to FIG. 3. The carrier ring support 230a of the pedestal 200 illustrated in FIG. 12 may have a similar structure as the carrier ring supports 230 illustrated in FIG. 3 except that the carrier ring support 230a has a protruding portion that extends upwardly from the peripheral portion 220 of the pedestal 200. In FIG. 12, like reference numerals as those in FIG. 3 denote like elements, and descriptions of the elements are omitted or briefly provided.

Referring to FIG. 12, the carrier ring support 230a protrudes from the peripheral portion 220 of the pedestal 200 by a predetermined amount, and may support the spacer 120. The lower surface 111 of the body 110 may be separated from the pedestal 200 by the carrier ring support 230a and the spacer 120. In this example, a first section of the carrier ring 100 may be seen as having a lower surface where the carrier ring 100 contacts the carrier ring support 230a, and the lower surface 111 may be considered as a second lower surface of the carrier ring 100 disposed at a level above the lower surface of the first section of the carrier ring.

That is, the first section may be a spacer 120 that along with the carrier ring supports 230a spaces the (second) lower surface 111 of the carrier ring 100 from the peripheral portion 220 of the pedestal. In this case, a vertical distance Ha between the lower surface 111 and the peripheral portion 220 of the pedestal 200 may be approximately the same as a sum of a height of the spacer 120 and a height of the portion of the carrier ring support 230a protruding from the peripheral portion 220 of the pedestal 200.

Because the spacer 120 and the carrier ring support 230a both contribute to separation of the lower surface 111 of the body 110 from the pedestal 200, even when one of the spacer 120 and the carrier ring support 230a is damaged, the lower surface 111 of the body 110 may remain separated from the pedestal 200.

FIG. 13 is a schematic cross-sectional view of an example of a CVD apparatus 10 according to the inventive concept.

Referring to FIG. 13, the CVD apparatus 10 may include a chamber 301, a pedestal 200, a carrier ring 100, a transport device including a transport arm 310, a jetting member 320, and a gas supply system 330.

The chamber 301 may delimit an inner space in which a deposition operation takes place. The chamber 301 may be a chamber in which a predetermined thin film is formed on a wafer W by CVD.

The chamber 301 may include a lower portion 301b and an upper portion 301a. The lower portion 301b may contain a plurality of stations (sub-chambers) each containing a respective pedestal 200, as illustrated in FIG. 14. The pedestal 200 may be any of the pedestals described with reference to FIGS. 1 through 3 and FIGS. 10 through 12.

Although not illustrated in FIG. 14, an entrance and an exhaust duct may communicate with the interior of the chamber 301. Wafers W enter or exit through the entrance. A reaction gas, a purge gas, or a reaction by-product may be discharged from the chamber 300 by means of the exhaust duct. The exhaust duct may be connected to a vacuum pump, and may include a pressure control valve, a flow control valve, or the like.

The carrier ring 100 may be placed on the pedestal 200 to surround the wafer W while the deposition operation is being performed. In addition, the carrier ring 100 may support the wafer W while the wafer W is being transported within the chamber 301. The carrier ring 100 may also be any of the carrier rings described above with reference to FIGS. 1 through 3 and FIGS. 8 through 12.

The transport arm 310 of the transport device may transport the carrier ring 100 between stations in the chamber 301. While the transport arm 310 transports the carrier ring 100, the wafer W may be supported by the carrier ring 100, and thus, the carrier ring 100 and the wafer W may be transported together. A transport arm drive mechanism, which may be referred to hereinafter simply as a driving member 311 of the transport device, controls driving of the transport arm 310, for example, vertical movement, horizontal movement, and/or rotational movement of the transport arm 310. To this end, the transport drive mechanism may comprise any known linear and/or rotary actuators for effecting the vertical and/or rotational movement of the transport arm 310.

The jetting member 320 may inject gas into the chamber 301 towards the wafer W on the pedestal 200. The jetting member 320 may receive a reaction gas, a purge gas, or the like from the gas supply system 330, and inject the gas onto the wafer W. The jetting member 320 may include a head 321, e.g., a showerhead, through which gas is jetted, and a conduit 323 that passes through an upper central portion of the chamber 301 and supports the head 321. The head 321 may have a disk shape, and gas outlets, through which a gas is jetted, may be formed in a lower surface of the head 321.

In some examples, the CVD apparatus 10 may perform some parts of a back end of line (BEOL) operation. For example, the CVD apparatus 10 may be used to form an MN layer in a BEOL operation. However, the CVD apparatus 10 is not limited to performing the above-described operation. For example, the CVD apparatus 10 may also be used in forming various insulation layers on the wafer W (on which transistors have been formed) or forming a metal wiring layer and/or an input/output pad of an interconnection.

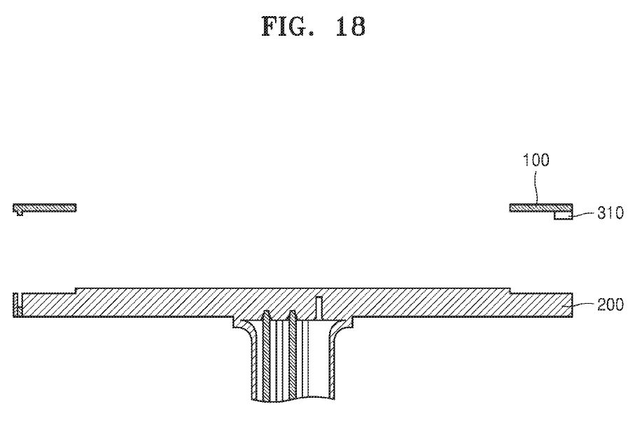

In some examples, a controller of the transport device may be configured to control the driving member 311 such that the transport arm 310 separates the carrier ring 100 from the pedestal 200 during times in which no deposition operation is being performed on the wafer W so that at such times the carrier ring 100 is not heated by the pedestal 200. For example, as illustrated in FIG. 18, while no deposition operation is performed on the wafer W, the carrier ring 100 may be vertically separated from the pedestal 200 by the transport arm 310.

To this end, the drive mechanism is operable to drive the transport arm 310 vertically between a first position (e.g. as shown in FIG. 13) at which the transport arm 310 engages the carrier ring 100 while the carrier ring is mounted to the pedestal 200 and a second position (FIG. 18) at which the carrier ring 100 is raised off of the pedestal 200 by the transport arm 310 and thereby separated from the pedestal 200. Therefore, during times at which the wafer W is not present on the carrier ring 100, the transport arm 310 may separate the carrier ring 100 from the pedestal 200. For example, the carrier ring 100 may be on standby while being separated from the pedestal 200, before the wafer W is fed into the chamber 301 and after the wafer W is discharged out of the chamber 301 after completion of the deposition operation on the wafer W.

Furthermore, in some examples of a method of processing substrates according to the inventive concept, e.g., in a batch processing method according to the inventive concept, the CVD apparatus 10 may not perform an in-situ cleaning operation. In a conventional CVD apparatus, an in-situ cleaning operation may be necessary to remove unnecessary sediment deposited in the chamber or on a surface of the carrier ring. The in-situ cleaning operation may be performed to remove a thin film deposited on an inner wall of the chamber and a surface of the carrier ring, and to raise a rate of operation of the CVD apparatus. However, according to an aspect of the inventive concept, growth rate of a film on the carrier ring 100 is significantly minimized Thus, more deposition operation cycles may be conducted than in a conventional CVD apparatus up to a point at which the thickness of a thin film formed on a surface of the carrier ring 100 reaches a predetermined thickness. Accordingly, a CVD apparatus 10 according to the inventive concept may have a higher preventive maintenance (PM) cycle than a conventional CVD apparatus and also a higher rate of operation (less downtime0.

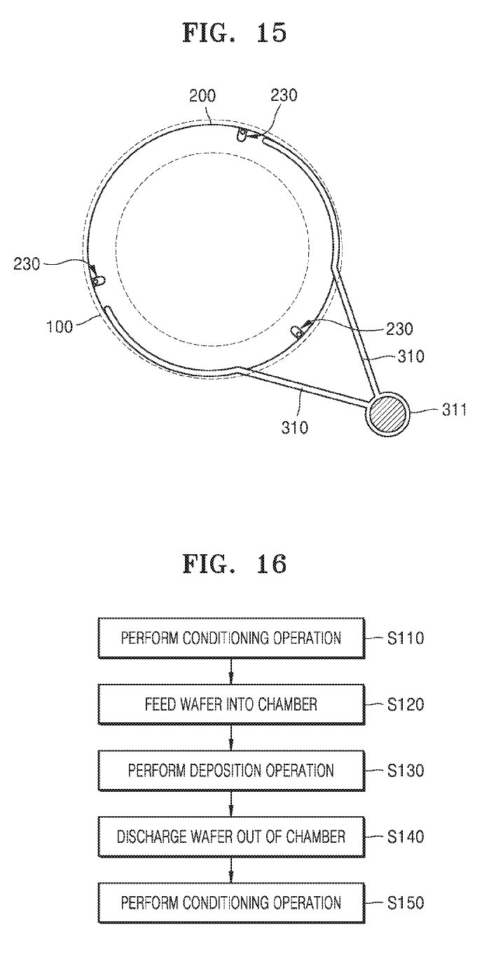

FIG. 14 is a plan view of the lower portion 301b of the process chamber 300 of the CVD apparatus 10 of FIG. 13, and FIG. 15 is a detailed view of the transport arm 310 illustrated in FIG. 14.

Referring to FIGS. 14 and 15, the lower portion 301b may include a plurality of stations, and each of the stations may include a respective pedestal 200. A deposition operation on wafers W present at two or more of the stations. The deposition operation may also be performed on a wafer W at only one station. In addition, while respective carrier rings 100 are illustrated as being disposed on each of the four pedestals 200 of the stations in FIG. 14, a respective carrier ring(s) 100 may also be disposed on only one or some of the four pedestals 200.

An end effector of the transport arm 310 may be configured to support a portion of a lower surface of the carrier ring 100 near an outer edge. At least a portion of the transport arm 310, i.e., the end effector may extend along an outer edge of the carrier ring 100. When in the position shown in FIG. 13, (the end effector of) the transport arm 310 is interposed between the upper surface of the peripheral portion 220 of the pedestal 200 and the lower surface 111 of the annular body of the carrier ring 100. In the illustrated example, the end effector has two fingers, each extending in an arc between adjacent ones of a respective pair of the carrier ring supports 230 when the transport arm 310 is in the position shown in FIG. 13.

Transportation of the wafer W between different stations may be performed using the transport arm 310 and the carrier ring 100. More specifically, the transport arm 310 may transport the carrier ring 100 and the wafer W among a plurality of stations by lifting, horizontally moving or lowering the carrier ring 100.

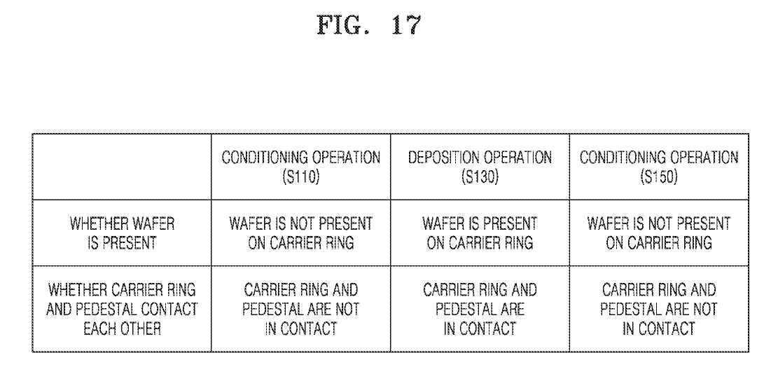

FIG. 16 is a flowchart of a manufacturing process of a semiconductor device, according to the inventive concept. FIG. 17 is a table showing whether a wafer is present and whether a carrier ring and a pedestal contact each other in conditioning operations S110 and S150 and a deposition operation S130 of FIG. 16. FIG. 18 is a conceptual view illustrating the carrier ring 100 and the pedestal 200 in a state in which they are not in contact with each other.

Referring to FIGS. 16 and 17, in an example of a method of manufacturing a semiconductor device, according to the inventive concept, a first conditioning operation S110, a wafer feeding operation S120, a deposition operation S130, a wafer discharging operation S140, and a second conditioning operation S150 may be sequentially performed.

More specifically, the first conditioning operation S110 may be performed without a wafer, and may be performed while the carrier ring is not in contact with the pedestal. Here, the conditioning operation may include various operations to provide a suitable environment for a deposition operation. For example, the conditioning operation may include a purge operation, a flushing operation, and a seasoning operation.

For example, as illustrated in FIG. 18, while the first conditioning operation S110 is performed, the transport arm 310 may lift the carrier ring 100 such that the carrier ring 100 is separated from the pedestal 200. In the state in which the carrier ring 100 is separated from the pedestal 200, which is at a high temperature, the carrier ring 100 is thus not heated by conduction by the pedestal 200 and may be cooled through heat transfer with the ambient of the chamber 300.

Next, a wafer is fed into the chamber in wafer feeding operation S120. In order to mount the wafer on the pedestal, the transport arm may lower the carrier ring such that the carrier ring is placed on the pedestal. The wafer fed into the chamber may be mounted on the pedestal, e.g., by lift pins described earlier, and the carrier ring may surround edges of the wafer.

Next, a deposition operation is performed in deposition operation S130 to form a thin film on a surface of the wafer. The deposition operation may be performed while the carrier ring is in contact with the pedestal. The deposition operation may be performed by repeating a plurality of cycles until desired thin film characteristics, for example, a desired thickness, are obtained.

However, the course of the deposition operation may include an operation of transporting the wafer in the chamber. That is, the deposition operation may be performed while the wafer is at more than one of the stations. In this case, while the wafer is transported, the carrier ring may be lifted, horizontally transported, or lowered via the transport arm. While the carrier ring is being lifted, horizontally moved, and lowered, the carrier ring does not contact the pedestal.

Next, when the deposition operation is completed, the wafer is discharged from the chamber in wafer discharging operation S140. When the wafer is discharged and is not present on the carrier ring anymore, the transport arm may lift the carrier ring. As the carrier ring is lifted, the carrier ring does not contact the pedestal and is not heated by the pedestal.

Next, the conditioning operation is performed again in the second conditioning operation S150. In this operation, the carrier ring 100 may not contact the pedestal 200. For example, as illustrated in FIG. 18, the carrier ring 100 may be lifted by the transport arm 310 to be separated from the pedestal 200. Because the carrier ring 100 does not contact the pedestal 200, heating of the carrier ring 100 by the pedestal 200 may be prevented, and the carrier ring 100 may be cooled by heat transfer with the ambient.

According to an aspect of a manufacturing method according to the inventive concept, while the deposition operation on the wafer is not performed, heating of the carrier ring by the pedestal at a high temperature may be prevented. Accordingly, by minimizing deposition of a thin film on a surface of the carrier ring, defects of a device otherwise caused due to exfoliation of the thin film deposited on the carrier ring may be obviated.

Although the inventive concept has been particularly shown and described with reference to examples thereof and using specific terms, these examples are provided so that this disclosure will fully convey the concept of the inventive concept, and not for purposes of limitation. Thus, various changes to and other equivalents of the disclosed examples will be apparent to one of ordinary skill in the art. Therefore, the scope of the inventive concept is defined not by the detailed description of the inventive concept but by the appended claims.

1-17. (canceled)

18. A chemical vapor deposition (CVD) apparatus comprising:
a chamber;
a pedestal disposed in the chamber and having a central portion dedicated to support a wafer and a peripheral portion extending around the central portion, an upper surface of the central portion being situated at a level above that of an upper surface of the peripheral portion;
a carrier ring disposed on the peripheral portion of the pedestal and mounted to the pedestal in a manner in which the carrier ring is freely separable from the pedestal in a vertical direction; and
a transport device including a transport arm configured to engage the carrier ring, and a drive mechanism to which the transport arm is operatively connected so that the transport arm is driven by the drive mechanism,
wherein the carrier ring has an upper radially inwardly facing part to surround the wafer supported by the pedestal and an upwardly facing surface extending radially inwardly of the upper radially inwardly facing part to support an outer peripheral portion of the wafer, and
the drive mechanism is operable to drive the transport arm vertically between a first position at which the transport arm engages the carrier ring while the carrier ring is mounted to the pedestal and a second position at which the carrier ring is raised off of the pedestal by the transport arm and thereby separated from the pedestal.

19. The CVD apparatus of claim 18, wherein the carrier ring comprises:
an annular body having a lower surface facing the upper surface of the peripheral portion of the pedestal; and
a spacer on a lower portion of the annular body near an outer periphery of the annular body, engaged with the pedestal and spacing the lower surface of the annular body from the upper surface of the peripheral portion of the pedestal.

20. The CVD apparatus of claim 19, wherein a lower surface of the spacer and the lower surface of the annular body are substantially parallel to each other.

21. The CVD apparatus of claim 20, wherein a vertical distance over which the lower surface of the annular body is separated from the upper surface of the peripheral portion of the pedestal is substantially identical to a vertical distance between the lower surface of the spacer and the lower surface of the annular body.

22. The CVD apparatus of claim 19, wherein the carrier ring further comprises a concave-convex section that is disposed between the spacer and an inner peripheral edge of the annular body and includes a convexity that tapers in a downward direction towards the upper surface of the peripheral portion of the pedestal.

23. The CVD apparatus of claim 18, wherein the pedestal comprises a carrier ring support at a radially outer part of the peripheral portion of the pedestal, the carrier ring support having a hole therein, and
the carrier ring has a first section that contacts the carrier ring support and a protrusion that extends downwardly from the first section and is received in the hole in the carrier ring support.

24. The CVD apparatus of claim 23, wherein the carrier ring support has an upper surface that contacts a lower surface of the first section of the carrier ring at a level above the upper surface of the peripheral portion of the pedestal.

25. The CVD apparatus of claim 24, wherein the carrier ring has a second lower surface facing the upper surface of the peripheral portion of the pedestal and disposed at a level above the lower surface of the first section of the carrier ring, whereby the first section is a spacer that along with the carrier ring supports spaces the second lower surface of the carrier ring from the peripheral portion of the pedestal.

26. A chemical vapor deposition (CVD) apparatus comprising:
a chamber;
a pedestal disposed in the chamber and including a central portion having an upper surface, a peripheral portion extending around the central portion and having an upper surface disposed at a level beneath that of the upper surface of the central portion, and carrier ring supports disposed along an outer circumference of the peripheral portion; and
a carrier ring mounted to the pedestal via the carrier ring supports,
wherein the carrier ring comprises an annular body having an upper surface disposed radially outwardly of the central portion of the pedestal and a lower surface disposed radially inwardly of the carrier ring supports, and
the lower surface of the annular body extends over and is vertically spaced from the upper surface of the peripheral portion of the pedestal.

27. The CVD apparatus of claim 26, wherein the annular body of the carrier ring consists of quartz or Y₂O₃.

28. The CVD apparatus of claim 26, wherein the carrier ring further comprises a spacer on a lower portion of the annular body, and
the spacer engages the carrier ring supports and spaces the lower surface of the annular body from the upper surface of the peripheral portion of the pedestal.

29. The CVD apparatus of claim 28, wherein the carrier ring supports have holes therein, respectively, and
the carrier ring further comprises protrusions that extend downwardly from the spacer into the holes in the carrier ring supports, respectively.

30. The CVD apparatus of claim 28, wherein the annular body has a radially inner peripheral edge adjacent to a radially outer peripheral surface of the central portion of the pedestal, and
the carrier ring further comprises a concave-convex section that is disposed between the spacer and the radially inner peripheral edge of the annular body, the concave-convex section including an array of convexities resting against the upper surface of the peripheral portion of the pedestal.

31. The CVD apparatus of claim 26, wherein the carrier ring supports protrude above the upper surface of the peripheral portion of the pedestal and contact the carrier ring at a level above that of the upper surface of the peripheral portion of the pedestal.

32. The CVD apparatus of claim 31, wherein the carrier ring supports contact the lower surface of the annular body of the carrier ring,
the carrier ring supports have holes therein, respectively, and
the carrier ring further comprises protrusions that extend downwardly from the lower surface of the annular body into the holes in the carrier ring supports, respectively.

33. The CVD apparatus of claim 31, wherein the carrier ring has a spacer at a lower portion thereof, the spacer having a lower surface disposed at a level below that of the lower surface of the annular body,
the carrier ring supports contact the lower surface of the spacer,
the carrier ring supports have holes therein, respectively, and
the carrier ring further comprises protrusions that extend downwardly from the spacer into the holes in the carrier ring supports, respectively,
whereby the spacer along with the carrier ring supports space the lower surface of the annular body of the carrier ring from upper surface of the peripheral portion of the pedestal.

34. A chemical vapor deposition (CVD) apparatus comprising:
a chamber;
a pedestal disposed in the chamber and having a central portion having an upper surface, a peripheral portion extending around the central portion and having an upper surface disposed at a level beneath that of the upper surface of the central portion, and carrier ring supports disposed along the peripheral portion of the pedestal;
a carrier ring mounted to the pedestal at the carrier ring supports, the carrier ring having an upper surface disposed radially outwardly of the central portion of the pedestal and a lower surface facing the upper surface of the peripheral portion of the pedestal; and
a transport device including a transport arm configured to engage the carrier ring, and a drive mechanism to which the transport arm is operatively connected,
wherein the carrier ring and carrier ring supports have complementary portions fitted to one another, the complementary portions configured such that the carrier ring is freely separable from the pedestal in a vertically upward direction,
the drive mechanism is operable to drive the transport arm vertically between a first position at which the transport arm engages the carrier ring while the carrier ring is mounted to the pedestal and a second position at which the carrier ring is raised off of the pedestal by the transport arm and thereby separated from the pedestal.

35. The CVD apparatus of claim 34, wherein the carrier ring also has an upper radially inwardly facing side surface, the upper surface of the carrier ring extending radially inwardly from a bottom of the upper radially inwardly facing side surface, whereby the upper radially inwardly facing side surface and the upper surface of the carrier ring together have the form of a nest.

36. The CVD apparatus of claim 34, wherein the carrier ring comprises an annular body,
the upper and lower surfaces of the carrier ring are upper and lower surfaces of the annular body, respectively,
the lower surface of the annular body extends over and is vertically spaced from the upper surface of the peripheral portion of the pedestal, and
the transport arm when in the first position is interposed between the upper surface of the peripheral portion of the pedestal and the lower surface of the annular body of the carrier ring.

37. The CVD apparatus of claim 34, wherein the transport arm has an end effector comprising two fingers.
